(19) United States
(12) Patent Application Publication
(10) Pub. No.: US 2003/0178718 A1
(43) Pub. Date: Sep. 25, 2003

(54) Hermetically enhanced plastic package for microelectronics and manufacturing process

(76) Inventors: Jonathan P. Ehly, San Diego, CA (US); Jack A. Rubin, San Diego, CA (US); Prem K. Sood, San Diego, CA (US); Frank J. Polese, San Diego, CA (US)

Correspondence Address: CHARMASSON & BUCHACA, 1545 HOTEL CIRCLE SOUTH, SUITE 150, SAN DIEGO, CA, 92108-3412, US

(21) Appl. No.: 10/290,070

(22) Filed: Nov. 5, 2002

Related U.S. Application Data
(60) Provisional application No. 60/338,503, filed on Nov. 5, 2001.
(60) Provisional application No. 60/403,018, filed on Aug. 12, 2002.

(51) Int. Cl. H01L 21/52

(52) U.S. Cl. 257/701; 257/703; 257/433; 257/728

(57) ABSTRACT

An hermetically enhanced hybrid microelectronic package of injection moldable plastic and ceramic parts, wherein a gas barrier is formed onto surfaces of the plastic parts through metalization. Further, interface surfaces between the plastic parts and any metal or ceramic parts are further treated to accommodate hermetically stable low temperature bonding such as soldering at a temperature which does not exceed the temperature limits of the plastic.

### PRIOR APPLICATION

This is a Formal Application claiming benefit of Provisional Patent Application Serial No. 60/338,503 filed Nov. 5, 2001 and Provisional Patent Application Serial No. 60/403,018 filed Aug. 12, 2002.

### FIELD OF THE INVENTION

This invention relates to microelectronic packaging and more specifically to injection molded plastic packaging for microelectronics.

### BACKGROUND OF THE INVENTION

A semiconductor die or chip is relatively fragile compared to its supporting circuitry, and is usually encased in a semiconductor die package to protect it from the outside environment. However, this package must allow communication with the die, electrically, thermally and, depending on the application, optically. Most preferably, the enclosure should seal as well as practically possible against the passage of gasses such as water vapor through it. The passage of moisture into the package interior can cause corrosion of the microcircuitry components. These requirements have caused microelectronic circuit packaging to become a complex science employing many structures and materials.

Most electronic microcircuit components require the use of structures which are capable of dissipating the heat generated by the active parts of the microcircuit. Moreover, those structures in direct contact with one another must have compatible thermal expansion characteristics. Otherwise, stresses caused by the disproportionate expansion may damage components, create separations between elements or otherwise reduce thermal dissipation efficiency and overall package hermeticity.

Most microelectronic packaging structures require a certain degree of resistance to the passage of gasses through the package walls and is quantified as hermeticity which is generally defined as the leak rate of a quantity of dry air at 25° C. measured in atmospheric cubic centimeters per second (atm cc/s) flowing through a leak path where the high-side pressure equals one atmosphere and the low-side pressure is one torr. A lower leak rate is therefore generally desirable.

Those packages having a plurality of discrete electrical inputs require dielectric separation of signal-carrying leads penetrating the package. Further, many applications benefit from selective input/output of the penetrating leads. The routing of the electrical interconnection between the outwardly extending leads and the inner pads has led to the development of so-called multilayer ceramic technology (MLC), as described in Microelectronics Packaging Handbook, Van Nostrand Reinhold publishers, New York 1989, pages 455-522 which provides for three-dimensional routing of interconnection lines.

Optoelectronic semiconductor packages such as the so-called butterfly-type package also include a cylindrical fiber-optic cable adapter pipe for penetrating through an end wall of the package housing. These parts, and a bottom heat spreader, leadframe, and cover are typically fabricated separately and later assembled to form the package. The parts are typically made from hermetically resistant materials. The heat spreader has a high thermal conductivity and thermal expansion characteristics compatible with adjacent structures and other components in the finished package. The parts have the capability of forming rugged and hermetically resistant bonds with each other. The leadframe materials are typically composed of copper, iron-nickel and iron-nickel-cobalt alloys. Such materials and their fabrication processes dictate the cost of the package.

It is well known to use materials such as composite metals such as copper-tungsten, copper-molybdenum, aluminum-silicon carbide, iron-nickel-silver, and iron-nickel-cobalt-silver for the heat spreader and multilayer ceramic structures for the feed-thrus which are available from Semx Corporation of Armonk, N.Y.

In an attempt to reduce the cost of these packages, it has been shown to use a low thermal expansion, dielectric thermoplastic material such as liquid crystal polymer (“LCP”). This material is generally described by Lusignea, Liquid Crystal Polymers: New Barrier Materials for Packaging October 1997, Packaging Technology and Engineering. Such material is capable of being injection molded to inexpensively form portions of the package as disclosed in Kato et al., U.S. Pat. No. 6,220,764. Further, as disclosed in this reference, elongated glass fiber filled LCP may be injected in such a way as to orient most fibers to adjust rigidity and expansion characteristics in a given dimension. It is also known to metal plate LCP with copper or gold for the purpose of creating circuit traces.

Referring now to FIGS. 1 and 2, injection molded LCP has been used to form portions of a butterfly-type opto-electronic package 1. The pre-die-attach finished package has a generally quadrangular housing 2 portion having opposite sidewalls 3,4 and opposite endwalls 5,6. Mounting wings 7 extend outwardly from the bottom edges of the endwalls. The housing sits atop and surrounds a heat spreader 8 made from a thermally conductive and thermal expansion compatible material such as copper-tungsten metal matrix composite upon which the die is later attached. A hollow cylindrical optic cable adapter 9 penetrates through one of the endwalls 5. A plurality of spaced apart electrically conductive leads 10 penetrate directly through each of the sidewalls 3,4 and terminate in inner contact pads 11 for later interconnection with the die through wire bonding.

The plastic is injection molded about the prepositioned heat spreader 8 and metal leads 10 in the mold to form integrated housing, mounting wings, and optic adapter portions avoiding the assembly steps described above. Such a package is commercially available from Silicon Bandwidth Company of Fremont, Calif. and available under the brand name OPTOSPYDER.

Although inexpensive to manufacture, the above-design can suffer from significant drawbacks. First, plastics including liquid crystal polymer-type plastics consistently have a leak rate of no less than 10⁻⁵ atm-cc/sec which limits use of the package to less hermetically demanding applications. Second, as disclosed in Kato et al., U.S. Pat. No. 6,220,764, the interface 13 between the metal feed-throughs and the plastic housing typically suffer from a localized degradation in hermeticity due to inability for the injection molded plastic to form an adequately reliable bond with the metal used for the feed-thru portion of the leads. This weakness is usually exacerbated by any thermal expansion mismatch between the metal leads and the plastic housing.

Lastly, each of the leads 10 forms a feed-through running directly through the sidewall 3 or 4 from the elongated outer section 12 leads to the inner pads 11. In this way the input/output from the die is not selectable. Oftentimes, in optical, radio frequency or microwave communication devices, it is advantageous to provide for some selectability or flexible assignability between the location of the outer lead sections and the inner bonding pads. In addition, for many higher frequency applications, control of the impedance of these feed-throughs is desirable. Such flexibility is not generally available in the direct feed-through design.

The invention arose from an attempt to address the above identified and other problems.

### SUMMARY OF THE INVENTION

The principal and secondary objects of this invention are to provide a less expensive, improved microcircuit package which allows greater hermetic integrity and stability, and assignability of the feed-throughs from outer lead portions to inner pads.

These and other objects are achieved by a hybrid ceramic and plastic package wherein the plastic portion is treated to have a hermetically enhancing gas barrier. Lead feed-throughs are preformed using a ceramic subassembly which is then bonded to the metalized interface surfaces of the plastic portion. The bond is formed through soldering or other well-known relatively low temperature bonding processes to form a pre-die-attach finished package.

### BRIEF DESCRIPTION OF THE DRAWING

FIG. 1 is a diagrammatic perspective view of a prior art butterfly-type optoelectronic package utilizing a plastic body with direct feed-throughs;

FIG. 2 is a diagrammatic cross-sectional view of the package of FIG. 1 taken along line 2-2;

FIG. 3 is a diagrammatic perspective view of the plastic integrated housing of the invention;

FIG. 4 is a diagrammatic cross-sectional view of the package of FIG. 3 taken along line 4-4;

FIG. 5 is a diagrammatic perspective view of a ceramic feed-through subassembly of the invention;

FIG. 6 is an illustrative cross-sectional top view of the feed-through subassembly of FIG. 4 taken along line 55; and

FIG. 7 is a diagrammatic flow-chart pictogram of the preferred process of the invention.

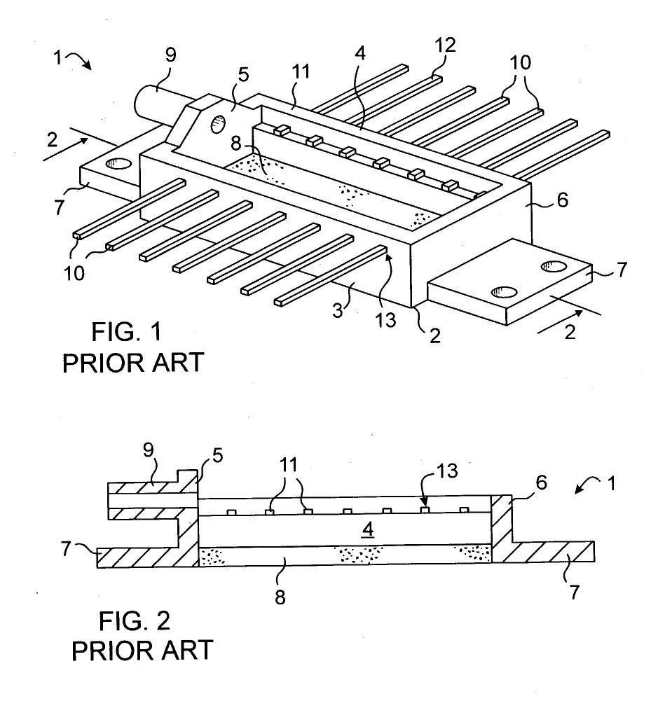

### DESCRIPTION OF THE PREFERRED EMBODIMENT OF THE INVENTION

The preferred embodiment of the invention will be described in relation to the manufacture of a butterfly-type optoelectronic pre-die-attach microcircuit package having a housing, a penetrating optical-type adaptor, mounting wings, heat spreader, and lead carrying feed-through subassemblies. It is clear to those skilled in the art that the invention is applicable to the manufacture of other microelectronic packaging structures such as RF and microwave communication device packaging which require hermetically sound interfaces between plastic and other component parts of different materials such as metals, composites, and ceramics, and to those applications requiring input/output selectability and impedance adjustability such as RF and microwave communication processing devices and modules.

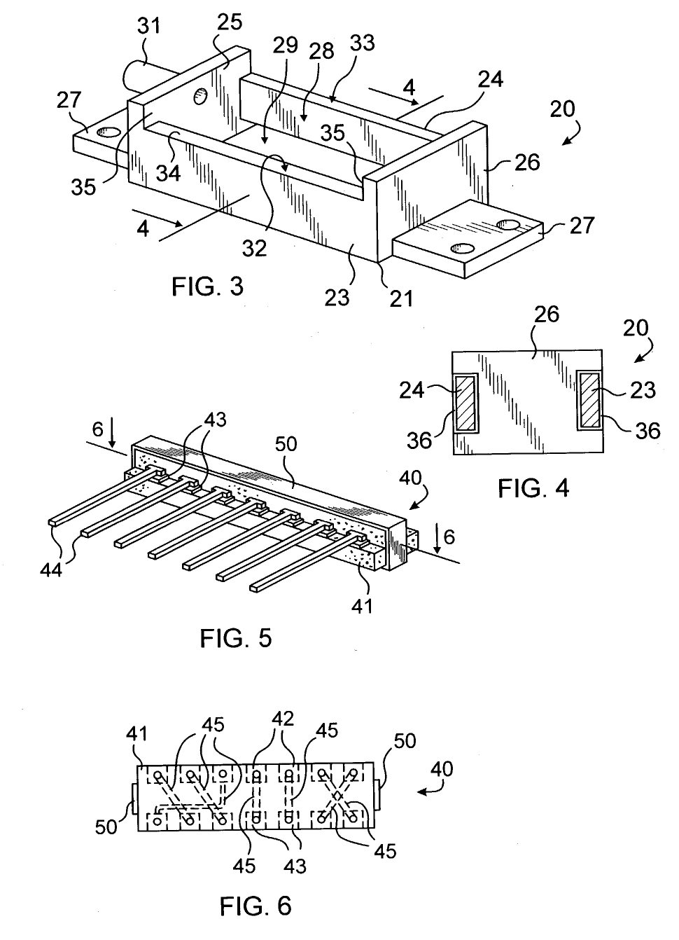

Referring now to the drawing, there is shown in FIGS. 3 and 4, an integrated housing portion 20 of a butterfly-type package according to the invention, which comprises a generally quadrangular body 21 having opposite sidewalls 23,24 and opposite endwalls 25,26. Mounting wings 27 extend outwardly from the bottom edges of the endwalls. The body surrounds an inner cavity 28 having a bottom opening 29 for accommodating a heat spreader and a top opening allowing die insertion. A hollow cylindrical optic cable adapter 31 penetrates through one of the endwalls 25. The sidewalls have upper troughs 32,33 each sized and located to accept a separately fabricated lead feed-through subassembly.

The housing is made from a liquid crystal polymer material sold under the brand name VECTRA T130 available from Ticona Company of Summit, New Jersey. This material is an approximately 30 percent glass fiber filled liquid crystal polymer having enhanced thermal characteristics which allow it to withstand temperatures of up to 300° C. in most microelectronic applications. In general, the type of polymer must be selected to be compatible with the thermal requirements of the package both in later processing and eventual device operation.

The integrated housing portion is formed from a single injection molded process well-known in the art as described in Kato et al., U.S. Pat. No. 6,220,764 incorporated herein by this reference.

A gas barrier is then formed through a metalization layer 36 coating the outer surfaces of the integrated housing including the interface surfaces, namely, the bottom 34 and end surfaces 35 of the troughs and those surfaces for contacting the heat spreader and any lid structure. It may be more convenient to form the metalization layer on all exposed surfaces of the integrated housing. Such metalization occurs through processes well known in the art such as metal sputtering, vacuum deposition, chemical vapor deposition, electroless plating, or cobined electroless an electrolytic plating which are conducted at temperatures under that which do not exceed the processing restrictions of the plastic. Depending on the process used, care must also be taken to ensure adequate bonding of the barrier layer to the underlying plastic. For example, in certain electroless plating processes the plastic surface should be activated through chemically treating with chromic acid followed by premetalizing with palladium/tin-chloride.

The metalization layer metals and processes are selected according to the processing restrictions of the plastic material and to create a thermally and hermetically reliable bond. Generally, the preferred material is nickel, however copper coated with nickel may also be used. The preferred thickness is between about 75 and 350 microinches.

Referring now to FIGS. 4 and 5, there is shown a ceramic lead feed-through subassembly 40 which comprises a ceramic body 41, carrying a plurality spaced apart of inner contact pads 42 and outer contact pads 43. Oblong outer leads 44 bond to outer pads. The inner pads are positioned for later interconnection with pads on the die through wire bonding.

The ceramic body 41 allows for selective device input/output through assignable, non-direct interconnection feed-throughs 45 between the outer pads and inner pads as shown illustratively through various examples in FIG. 6.

The feed-through subassembly 41 is preferably formed through a multilayer cofired ceramic process well known in the art and as described in Arrhenius U.S. Pat. No. 3,423,517, incorporated herein by this reference. This process allows placement of an outer layer of high melting point metal such as tungsten or molybdenum. This layer is then subsequently plated with nickel or nickel and gold to form an outer metal layer 50 contacting the top, bottom and side surfaces of the ceramic body which are intended to bond to the corresponding metalized surfaces of the feed-through trough 32 of the plastic integrated housing and any lid structure to be added post die-attach.

Interface surfaces between the heat spreader and integrated housing are also similarly treated to accept a hermetically enhanced bond through creation of outer layer of bondable metal such as nickel, or nickel and gold.

The interface surfaces are then bonded together using techniques well-known in the art. Care shall be taken that such bonding does not damage any associated structures. Low temperature soldering such as gold-tin soldering which typically occurs at temperatures no greater than 280° C. is preferred. Other low temperature bonding methods such as sonic or laser welding may be used. Since secondary processing of the package and die typically involves temperatures above 280° C., ultra low temperature solders such as indium may not be useful.

The resultant package therefore preferably exhibits a leak rate of less than 10⁻⁵ atm cc/s, more preferably a leak rate of less than 10⁻⁶ atm cc/s, even more preferably a leak rate of less than 10⁻⁷ atm cc/s, and most preferably a leak rate of less than 10⁻⁸ atm cc/s.

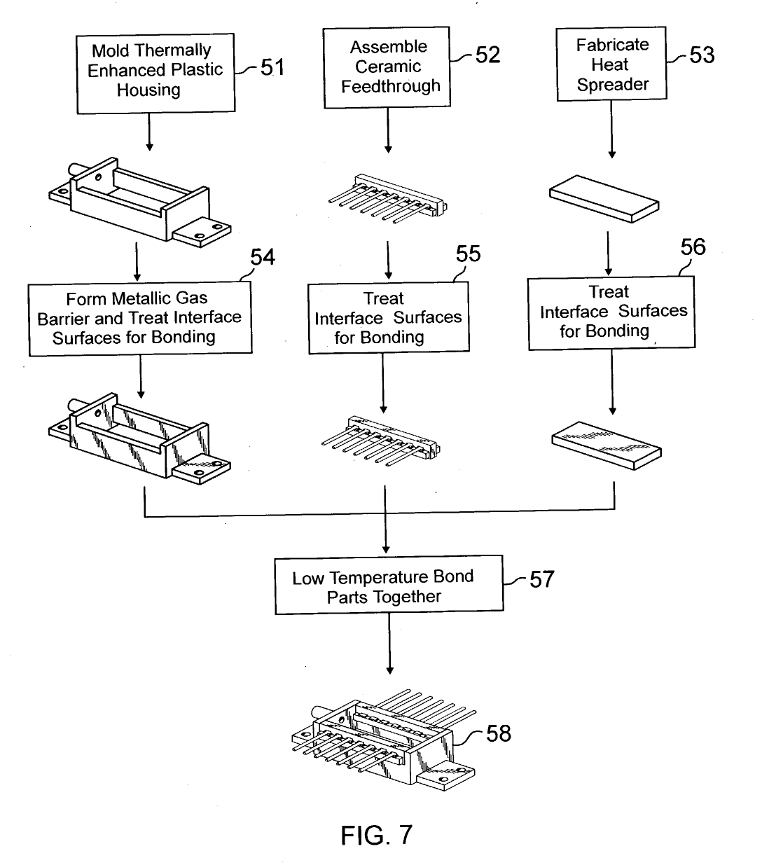

Referring now to FIG. 7, there is shown the preferred processing steps for forming the hybrid thermoplastic and other material package of the invention. The steps include the separate molding of the plastic portion of the package 51, the assembly of the ceramic feed-through subassembly 52 and the fabrication of the heat-spreader 53. A gas barrier is then formed on the integrated housing in the form of an outer metalization layer 54. The metalization layer extends to cover the interface surfaces between the integrated housing and other parts and thereby treat them for later hermetically enhanced bonding. The interface surfaces on the lead feed-through subassembly 55 and heat spreader 56 are also treated such as through plating with a layer of nickel to accommodate later hermetically enhanced bonding. Often times, it is more convenient for the entire plastic housing part to be entirely metalized as is true with the heat spreader. For the feed-through subassembly, the bond enhancing treatment should occur on those interface surfaces to be in contact with other portions of the package. The individual parts are then bonded together 57 using a low temperature solder such as gold-tin solder wherein the temperature does not exceed 280 C.° which is below the maximum temperature of the plastic material, to form the final die-ready package 58.

### EXAMPLE

An amount of glass fiber reinforced-type liquid crystal polymer available from Ticona Company under the brand name VECTRA T130 is selected and injection molded using well-known techniques to form an integrated housing of a butterfly-type optoelectronic package. All exposed surfaces of the housing are then electroless plated with a layer of nickel to a thickness of between about 100 microinches.

A ceramic leadframe subassembly is separately fabricated using a multilayer cofired ceramic process well known in the art. Interface surfaces of the feed-through subassembly body are formed to have a layer of tungsten. The tungsten is then plated with a layer of nickel to a thickness of between about 75 and 350 microinches.

A copper-tungsten heat spreader is separately fabricated using techniques well-known in the art. The entire exposed surface of the spreader was plated with a layer of nickel to a thickness of between about 75 and 350 microinches.

The heat spreader was then soldered to the integrated housing using gold-tin solder. The ceramic feed-through subassembly was then soldered to the metalized troughs of the integrated housing using gold-tin solder to form the die-ready finished package.

The exposed metallic surfaces were then plated with a layer of gold having a thickness of between about 50 and 250 microinches.

For testing purposes the package was then sealed by a soldered lid to test hermeticity and was found to have a leak rate of no more than 10⁻⁸ atm cc/s of air at 25° C.

While the preferred embodiments of the invention have been described, modifications can be made and other embodiments may be devised without departing from the spirit of the invention and the scope of the appended claims.

What is claimed is:

1. A hybrid plastic and ceramic microelectronic circuit package comprises a plastic body having a gas barrier formed thereon.

2. The package of claim 1, wherein said barrier comprises a first metalized layer; and wherein said package further comprises:
a ceramic body having a second metal surface;
wherein said first and second surfaces are bonded together.

3. The package of claim 1, wherein said plastic body comprises liquid crystal polymer material.

4. The package of claim 2, wherein said ceramic body is a multilayer co-fired ceramic body having assignable feedthroughs.

5. The package of claim 1, wherein said metalized surface comprises a metal selected from the group consisting of nickel, copper, and nickel-gold.

6. The package of claim 1, wherein said package has a leak rate of less than about 10⁻⁵ atm cc/s.

7. The package of claim 1, wherein said package is selected from the group consisting of butterfly-type optoelectronic packages, and radio frequency and microwave communication processing packages and modules.

8. The package of claim 2, wherein said first and second surfaces are soldered together.

9. The package of claim 2, wherein said first and second surfaces are sonic or laser welded together.

10. The package of claim 2, wherein said surfaces are soldered using solders selected from the group consisting of gold-tin solder, lead-tin solder, lead-tin-silver solder, lead-indium solder, tin-bismuth solder, tin-lead-bismuth solder, and tin-indium solder.

11. A method for fabricating a hybrid plastic and ceramic microelectronic circuit package comprises:
molding a plastic body;
fabricating a ceramic body;
forming a gas barrier on a first surface of said plastic body;
forming a bondable a second surface on said ceramic body; and
bonding together said first and second surfaces, wherein said bonding occurs at a temperature below a melting point of said plastic body.

12. The method of claim 11, wherein said molding comprises injection molding of a liquid crystal polymer.

13. The method of claim 11, wherein said fabricating comprises creating a multilayer cofired ceramic body having assigned feed-throughs.

14. The method of claim 11, wherein said forming a gas barrier comprises metalizing said first surface with a first metal.

15. The method of claim 14, wherein metalizing said first surface comprises depositing said first metal through electroless plating, combined electroless and electrolytic plating, sputter deposition, vacuum deposition, or chemical vapor deposition.

16. The method of claim 14, wherein said first metal is selected from the group consisting of nickel, copper, and nickel-gold.

17. The method of claim 11, wherein said bonding comprises soldering with a solder selected from the group consisting of gold-tin solder, lead-tin solder, lead-tin-silver solder, lead-indium solder, tin-bismuth solder, tin-lead-bismuth solder, and tin-indium solder.

18. The method of claim 11, wherein said bonding comprises sonic welding or laser welding.
